(19) United States
(12) Patent Application Publication
(10) Pub. No.: US 2017/0141278 A1
(43) Pub. Date: May 18, 2017

(54) LED ASSEMBLY FOR LED PACKAGE WITH SIDEWALL ELECTRODES

(71) Applicant: Toshiba Corporation, Tokyo (JP)

(72) Inventors: Norihito Hamaguchi, Morgan Hill, CA (US); Chao-Kun Lin, San Jose, CA (US)

(21) Appl. No.: 14/944,038

(22) Filed: Nov. 17, 2015

(51) Int. Cl. H01L 33/62; H01L 33/48; H01L 33/64; H01L 33/38

(52) U.S. Cl. CPC H01L 33/62; H01L 33/385; H01L 33/483; H01L 33/644

(57) ABSTRACT

The present disclosure provides a novel light-emitting diode assembly comprising a housing and an LED package having sidewall electrodes. The housing comprises sidewalls with contacts that are in electrical connection with electrodes of the LED package. The electrodes of the LED package are substantially exposed along the sidewalls of a resin carrier layer of the LED package.

### FIELD OF THE INVENTION

The present invention relates to a novel LED assembly comprising a novel light-emitting diode (LED) housing and a novel LED package having sidewall electrodes.

### BACKGROUND OF THE INVENTION

LED packages, or packaged LEDs, serve important functions for LEDs. LED packages protect LED dies from the environment and allow the LED dies to interface electrically and thermally with printed circuit boards. Furthermore, LED packages provide mechanical support, and enhance the light emission efficiency from the LED die.

FIG. 1 illustrates a conventional LED package 100. The package 100 includes a LED die 160 attached to a ceramic substrate 110b (e.g., AlN or Al2O3) via a top electrode 190. The LED die 160, which comprises a LED substrate 140, a light emitting layer 130, and a phosphor layer 120, is conventionally attached to the top electrode 190 with die-attach epoxy or solder (not shown). The LED die 160 is bonded to the top electrode 190 of the substrate 110b using a die-bonder, and a separate process is required to attach a bond wire 150, which electrically connects the LED die 160 to the top electrode 190 on the substrate 110b. There are electrical conducting vias 110a built into the substrate 110b to electrically connect the top electrode 190 and electrical contact pads 170a. Thermal pad 170b facilitates heat dissipation from the LED package 100 to a heat sink (not shown). Finally, a molded silicone dome 180 is formed on top of the LED die 160. A completed conventional LED package 100 is then ready for use and surface-mountable to printed circuit boards or a heat sink.

The fabrication steps of attaching the bond wire 150 and forming the molded silicone dome 180 are typically performed using die-level processing techniques. Issues with die-level processing include increased costs and manufacturing times as the steps must be performed individually on each die. In other words, the bond wire 150, phosphor layer 120, and silicone dome 180 are laboriously formed on each individual die after the individual dies have been formed by dicing a wafer.

Another issue with a conventional LED package such as the one shown in FIG. 1 is the cost associated with using die-level processing and packaging techniques to fabricate the LED package. For example, the cost of die bonding is high because it requires expensive die bonders and the process of die bonding is a high cost operation as each LED die must be picked and transferred individually. The U.S. Department of Energy published a report—Bardsley et al., “Manufacturing Roadmap—Solid State Lighting Research and Development” (August 2014)—which is incorporated herein by reference. The report breaks down various LED Cost Drivers for high-power LED packages and concluded that a majority of the costs are attributable to packaging costs associated with die-level processing (i.e., the costs associated with performing steps on each die on the wafer). According to the report, conventional packaging costs account for 61% of the total cost for high-power LED packages. With most of the costs for manufacturing conventional LED packages tied to die-level processes, the report suggests that cost savings for fabricating conventional LED packages could be achieved by performing more of the packaging processes at the wafer level. Wafer-level processing of an LED package refers to packaging the LED while it is still part of the wafer; in contrast, die-level processing acts on each LED package individually. Examples of die-level processing in fabricating conventional LED packages include the steps of wire bonding, phosphor coating, and formation of the silicone dome.

As such, the report recognized the long-felt need for an improvement to conventional LED packages and their respective fabrication methods by performing packaging activities at a wafer level in order to reduce the costs for LED packages.

Yet another issue is the limited options for housing or packaging a conventional LED package 100, which typically are soldered or glued onto the circuit board. Relying on solder or glue to attach the LED package to the circuit board presents several issues. For example, soldering and gluing the LED packages limits the number of mounting options and electrical connections available. Moreover, attaching an LED package 100 to a circuit board using an inflexible material such as solder or glue may also result in cracks to the LED package 100 or other stress-related reliability problems arising from the difference in thermal expansion between the LED package 100 and the circuit board. Replacing failed LED packages that have been glued or soldered is also difficult, as it would require carefully removing the failed LED package and the circuit board, and re-soldering a new LED package.

Another issue with the conventional LED package 100 is the exposure of the sidewalls of LED substrate 140 when a LED with an absorbing substrate is used in the package 100. The exposed sidewalls of the LED substrate 140 compromise the efficiency of the LED package 100 because they absorb light emitted from the light emitting layer 130 when light is reflected within the silicone dome 180. To prevent the exposed sidewalls from absorbing light and thereby improve efficiency of light output, conventional LEDs generally require yet another step of applying a reflective coating (not shown) to cover the exposed sidewalls.

Accordingly, there remain long-felt needs to reduce the costs of producing LED packages that utilizes existing manufacturing processes and to increase the types of mounting and housing options for the package at a low cost without requiring significant changes to the manufacturing process.

### SUMMARY

Having the electrodes on the sidewalls of an LED package allows a variety of configurations to accommodate the package. In one embodiment, a light-emitting diode (LED) assembly comprises a packaged LED. The packaged LED comprises a first electrode that is substantially exposed along a first sidewall of a resin carrier layer of the packaged LED, and a second electrode that is substantially exposed along a second sidewall of the resin carrier layer; and a housing accommodating the packaged LED. The housing comprises a first contact positioned on a first inward facing sidewall of the housing and electrically connected to the first electrode of the packaged LED, and a second contact positioned on a second inward facing sidewall of the housing and electrically connected to the second electrode of the packaged LED.

### BRIEF DESCRIPTION OF THE FIGURES

FIG. 1 provides a cross-sectional view of a conventional LED package.

FIG. 2A-C provide views of an LED package according one embodiment of the present disclosure.

FIG. 3 provides a cross-sectional view of an LED package according to another embodiment of the present disclosure.

FIG. 4 provides a plan view of an LED package according to another embodiment of the present disclosure.

FIG. 5 provides a plan view of an LED package according to another embodiment of the present disclosure.

FIG. 6 provides a plan view of an LED package according to another embodiment of the present disclosure.

FIGS. 7A-7K provide views of the steps in the fabrication process according to one embodiment of the present disclosure.

FIGS. 8A-8C provide views of the steps in the fabrication process according to one embodiment of the present disclosure.

FIG. 9 provides a plan view of an LED wafer according to one embodiment of the present disclosure.

FIGS. 10A-10F provide views of the steps in the fabrication process according to one embodiment of the present disclosure.

FIGS. 11A-11B provide views of an LED assembly according to one embodiment of the present disclosure.

FIG. 12 provides a view of an LED assembly according to another embodiment of the present disclosure.

FIGS. 13A-13B provide views of an LED assembly according to another embodiment of the present disclosure.

FIG. 14 provides a cross-sectional view of an LED assembly according to another embodiment of the present disclosure.

FIG. 15 provides a cross-sectional view of an LED assembly according to another embodiment of the present disclosure.

FIGS. 16A-16B provide views of an LED assembly according to another embodiment of the present disclosure.

FIG. 17 provides a view of an LED assembly according to another embodiment of the present disclosure.

FIGS. 18A-18B provide views of an LED assembly according to another embodiment of the present disclosure.

FIGS. 19A-19B provide views of an LED assembly according to another embodiment of the present disclosure.

FIGS. 20A-20B provide views of an LED assembly according to another embodiment of the present disclosure.

FIG. 21 provides a view of an LED assembly according to another embodiment of the present disclosure.

### DETAILED DESCRIPTION OF THE INVENTION

A novel LED package with sidewall electrodes and a novel LED assembly comprising a housing and the LED package will now be described more fully with reference to the accompanying drawings. The drawings are not necessarily drawn to scale and certain features of the disclosure may be shown exaggerated in scale or in schematic form in the interest of clarity and conciseness.

In describing various embodiments, specific terminology is employed for the sake of clarity. However, the disclosure is not intended to be limited to the specific terminology used in this specification. It is to be understood that each specific element includes all technical equivalents, which operate in a similar manner to accomplish a similar purpose.

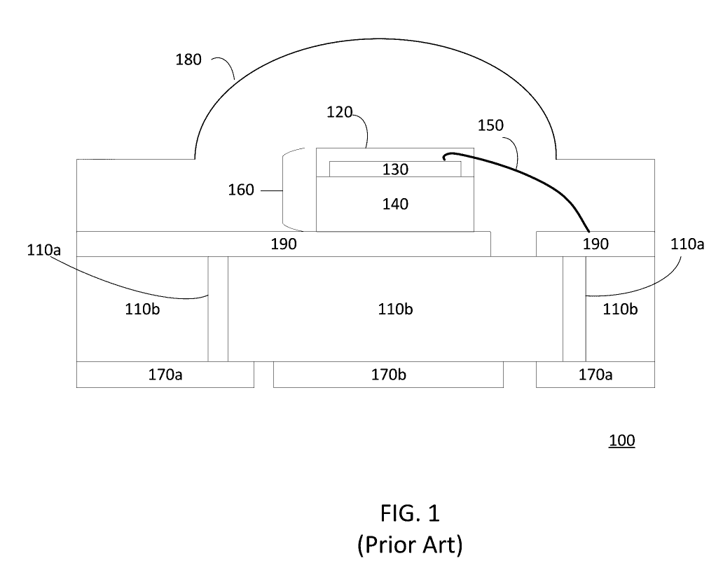

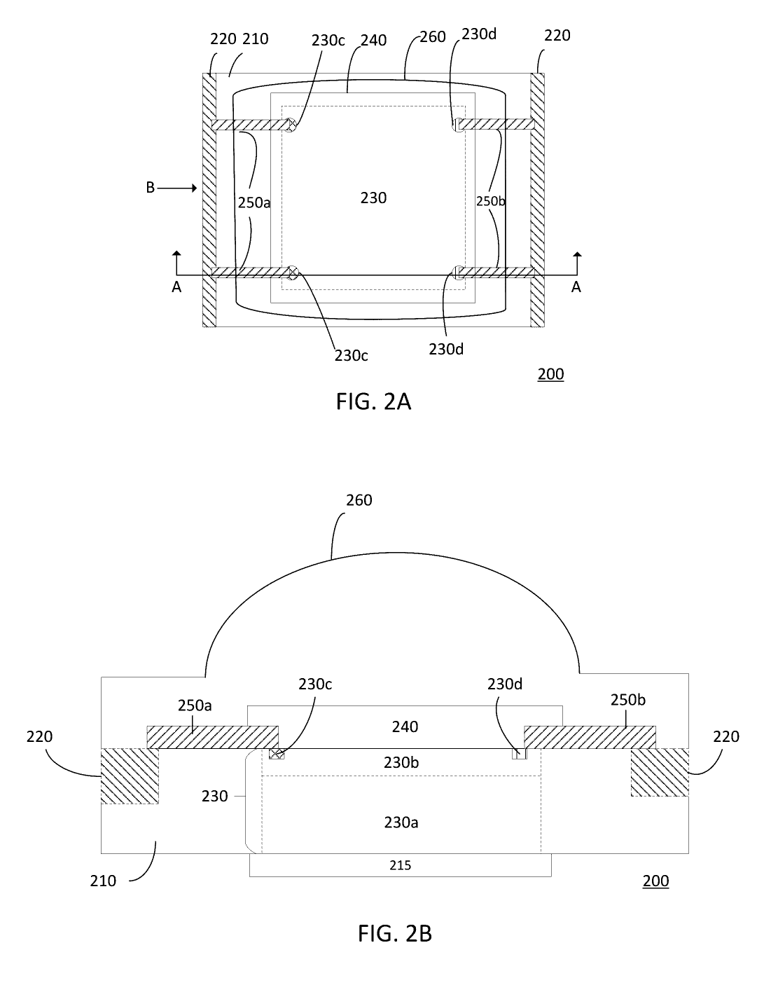

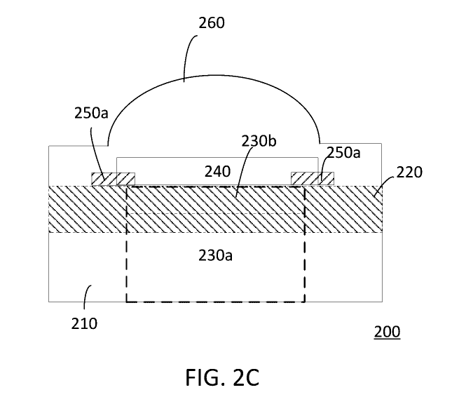

FIG. 2A provides a plan view of LED package 200. As shown in this view, the LED die 230 is electrically connected to wires 220 by metal interconnects 250a connected to the n-contact pads 230c of the LED die 230 and metal interconnects 250b connected to the p-contact pads 230d of the LED die 230. In one embodiment, metal interconnects 250a may be a redistribution layer. A redistribution layer performs the function of spreading the electrical contact points of the LED die 230 that increases the amount of surface area on which electrical contacts may be connected. The metal interconnects 250a and 250b are formed on an upper surface of a resin carrier layer 210 and replace a conventional bond wire (e.g., bond wire 150 of FIG. 1). N-contact pads 230c and p-contact pads 230d may be positioned anywhere on the LED die 230 that allows the metal interconnects 250a and 250b to be formed to electrically connect the LED die 230 to wires 220. In one embodiment, the n-contact pads 230c and p-contact pads 230d are located near the corners of the upper surface of the LED die as shown in FIG. 2A. Also shown are a phosphor layer 240 and a silicone dome 260.

FIG. 2B is a cross-sectional view of an LED package 200 taken along the A-A direction (as shown in FIG. 2A). The LED package 200 comprises the wires 220 and a single LED die 230, which includes at least a light emitting layer 230b and a LED substrate 230a, according to one embodiment of the present disclosure. The LED package 200 comprises the resin carrier layer 210, which may comprise for example, an epoxy molding compound.

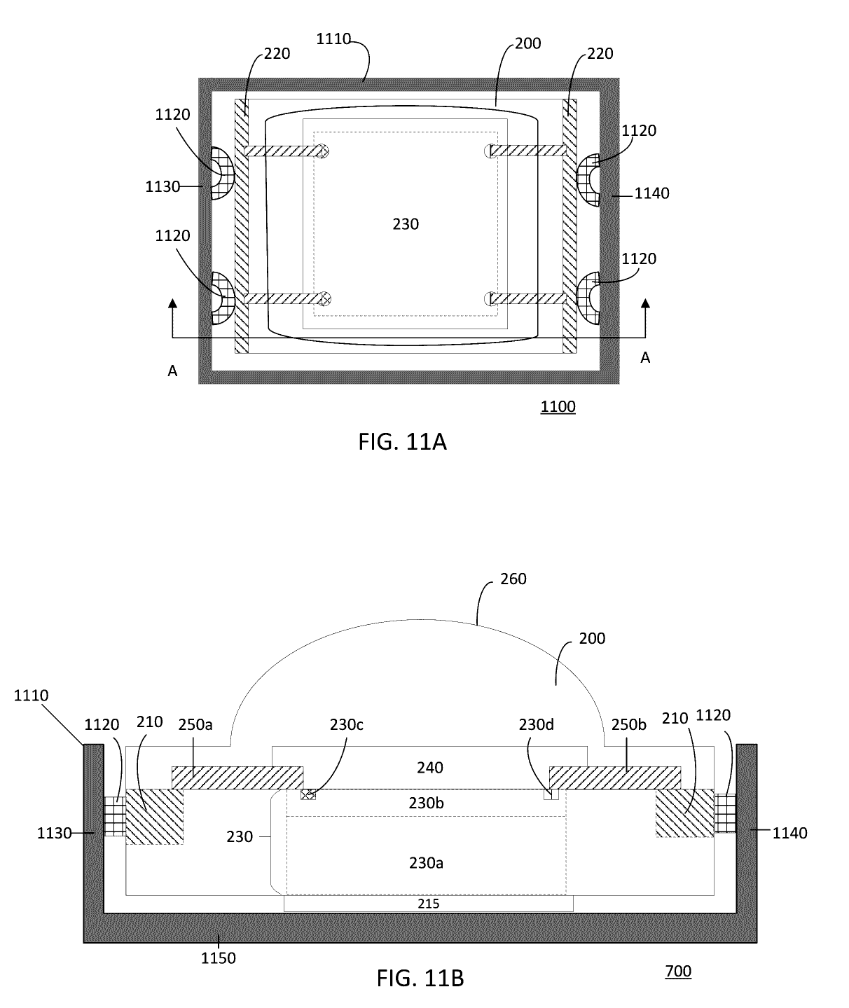

The wires 220 act as electrodes for the LED package 200. The upper and side surfaces of wires 220 are substantially exposed at the upper and side surfaces of the resin carrier layer 210, respectively. The novel positioning of the wires 220 along the sidewalls of the LED package 200 provides a number of benefits over conventional LED packages (e.g., 100 of FIG. 1) that are generally soldered or glued to circuit boards through electrical connections located at the bottom of the LED packages. Here, providing the wires 220 on the sidewall of the LED package 200 overcomes reliance on solder or glue and allows for the use of different types of housings. Housings are discussed in further detail later with respect to FIGS. 11A-21.

Despite the conductive wires 220 being exposed at the upper and side surfaces, the wires 220 are also substantially embedded within the resin carrier layer 210, in order to secure the wires 220 in place.

Physical properties of the wires 220 may vary. In one embodiment, the wires 220 may be comprised of copper. However, the wires 220 may be made of any electrically conductive material, such as aluminum or other metal.

Wires of any shape may be used as long as the properties allow for wires 220 to provide sufficient current to the LED dies 230. Wires 220 preferably have a flat surface at the exposed upper and side surfaces of the resin carrier layer 210, such as wires with a square or rectangular profile. Wires 220 can be solid or hollow. If using hollow wires, a recess in the sidewall is created when dicing along the wire. As will be discussed further below with respect to the housing of the LED package 200, this recess may be used to prevent contacts of the housing from slipping in a vertical direction when in direct physical contact with the LED dies 230. Other additional benefits of hollow wires are reduced cost and increased surface area (within the recess), which provide a larger contact area with a larger current carrying capacity and extra measure for mechanically securing the package.

Wires 220 having a flat surface have added benefit during the fabrication process because flat surfaces provide a larger surface area with which to adhere the wires 200 to the resin carrier substrate 210, a larger tolerance for dicing accuracy, and with which to electrically connect to the LED die 230. Moreover, the size of the wires 220 may be increased to increase the surface area and provide larger electrode areas on the sidewall of the LED package 200. In one embodiment, one wire 220 may act as a cathode and a second wire 220 may act as an anode for the LED package 200.

Metal interconnects 250a and 250b electrically connect wires 220 to the LED die 230. Specifically, the metal interconnects 250a and 250b electrically connect the upper exposed surfaces of wires 220 to the exposed upper surfaces of LED dies 230.

Metal interconnects 250a and 250b are shown formed on top of the resin carrier layer 210 but other embodiments are possible. For example, the metal interconnects 250a and 250b may also be partially or substantially embedded in the resin carrier layer 210. In one embodiment, the design of the LED package 200 purposefully omits the conventional bond wire (e.g., bond wire 150 shown in the conventional LED package 100 of FIG. 1). Comparing the novel LED package 200 with the conventional LED package 100, the bond wire 150 of conventional LED package 100 is suspended over the LED die 160 and substrate 110b, which impedes the application of a phosphor coating and formation of the silicone dome 180. By removing the bond wire, as is done in LED package 200, the fabrication of the LED package 200 is simplified. In place of conventional bond wire, metal interconnects 250a and 250b are incorporated as described in the present disclosure.

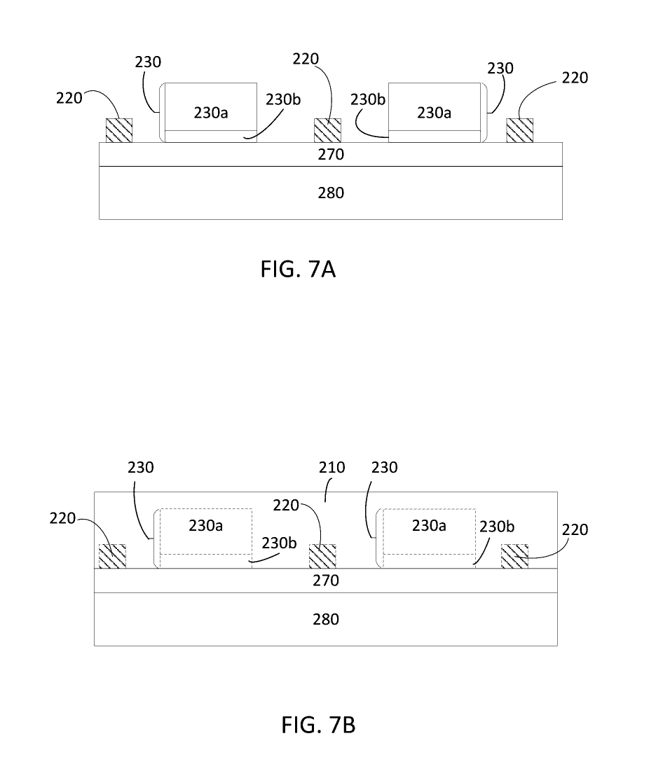

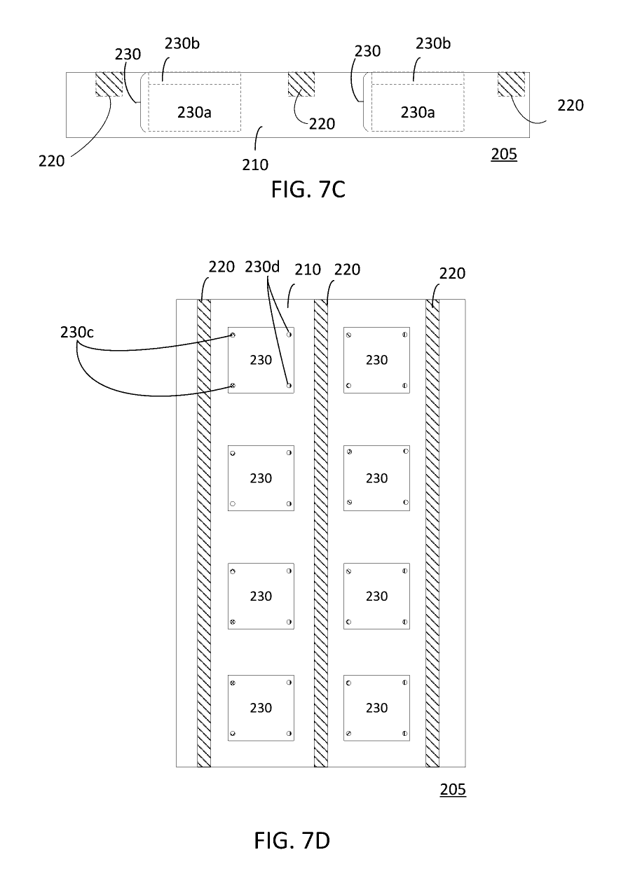

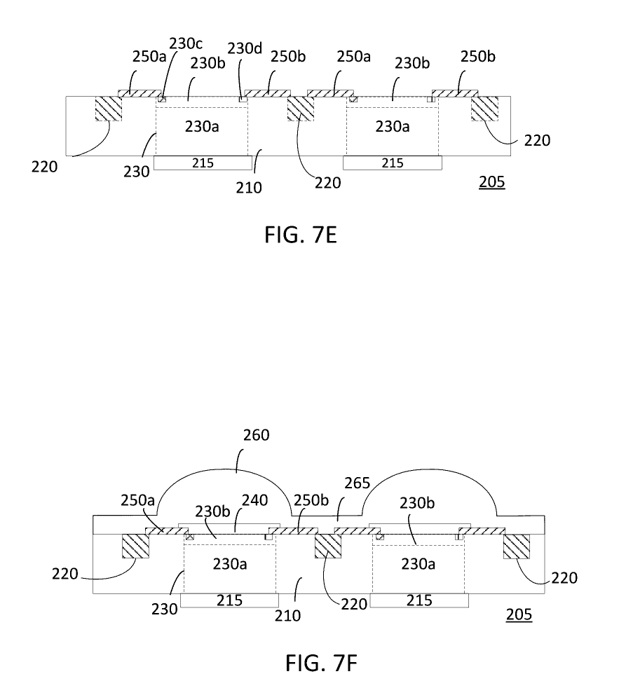

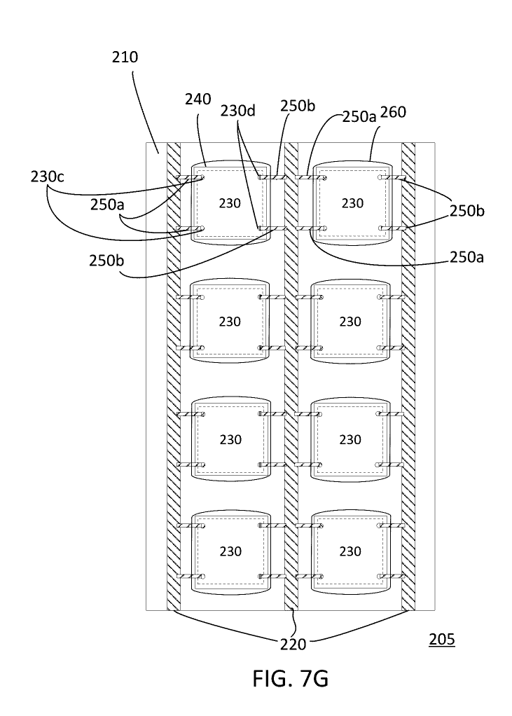

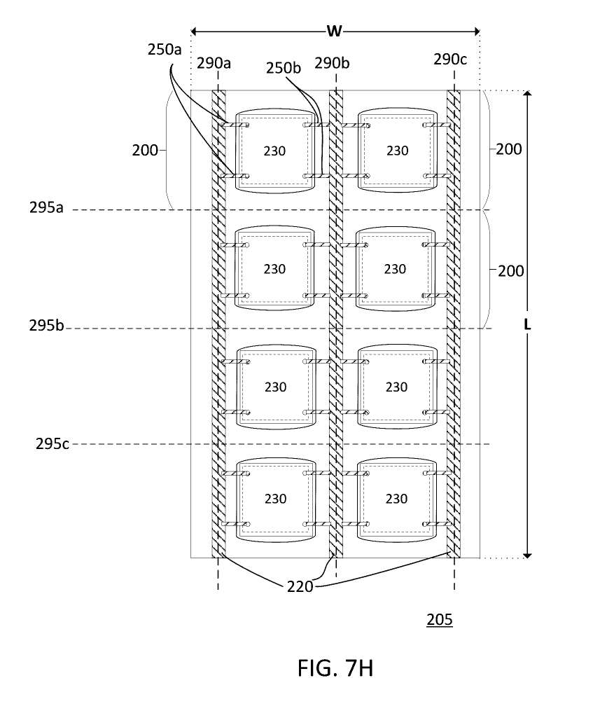

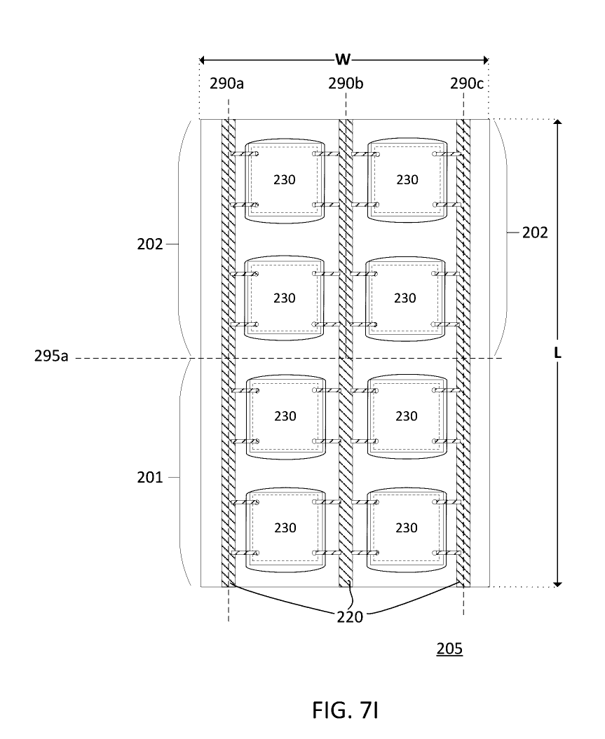

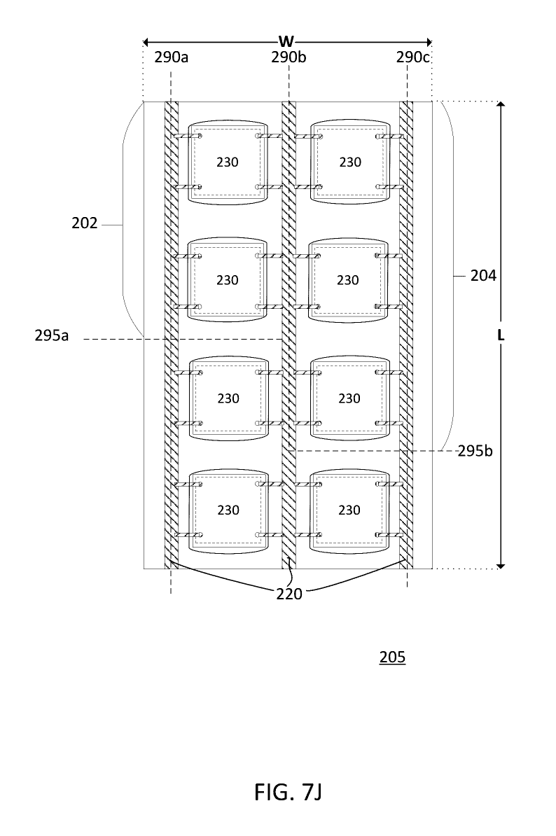

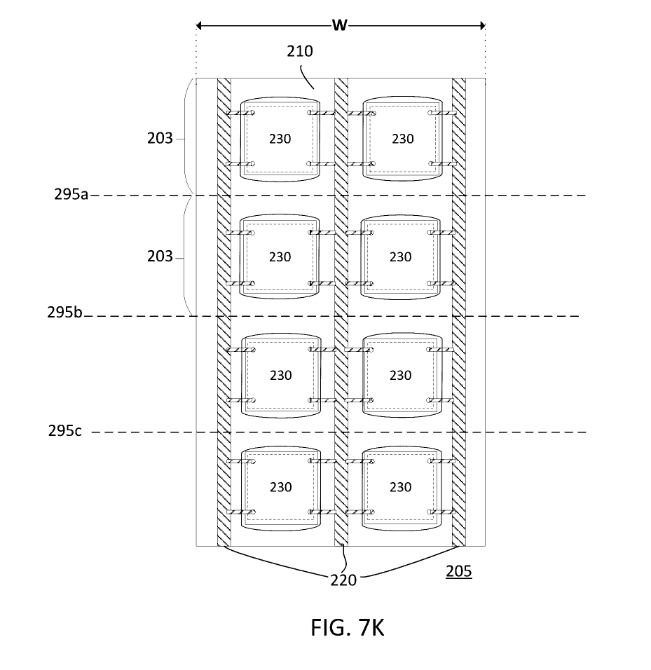

That is, by replacing the bond wire with metal interconnects 250a and 250b of LED package 200, steps that traditionally required die-level processing can now be performed advantageously using wafer-level processing to fabricate the LED package 200. For example, the metal interconnects 250a and 250b, phosphor layer 240, and the silicone dome 260 may all be deposited or applied to the LED package 200 using wafer-level processing methods. These process steps are discussed in more detail with regard to FIGS. 7A-7K below.

The LED die 230 is substantially embedded within the resin carrier layer 210 by, for example, locating the LED substrate 230a of the LED die 230 within the resin carrier layer 210 while leaving exposed the upper surface of the light emitting layer 230b of the LED die 230 at the upper surface of the resin carrier layer 210. In one embodiment, the upper surface of the light emitting layer 230b is substantially planar with respect to the upper surface of the resin carrier layer 210. It is recognized that there may be variations in the fabrication process resulting in a substantially parallel relationship between the upper surface of the light emitting layer 230b and the upper surface of the resin carrier layer 210. That is, in one embodiment, the upper surface of the light emitting layer 230b may protrude from the upper surface of the resin carrier layer 210, but would still maintain a parallel relationship with each other.

The LED package 200 further comprises a phosphor layer 240 and a silicone dome 260. The phosphor layer 240 may be formed on the exposed upper surface of the light emitting layer 230b using wafer-level processing. The purpose of the phosphor layer 240 is to allow the LED package 200 to produce a different colored light such as white light than that is output from the light emitting layer 230b, improve the light extraction efficiency, and direct the light beam from the light emitting layer 230b.

FIG. 2C provides a side view of the LED package 200 in the B direction as shown in FIG. 2A. FIG. 2C shows wire 220 exposed along a length of sidewall of the LED package 200. In this view, phosphor layer 240 and metal interconnects 250a are visible but metal interconnects 250b (not shown) are situated behind metal interconnects 250a and are not visible. LED substrate 230a and light emitting layer 230b are encapsulated within the resin layer 210.

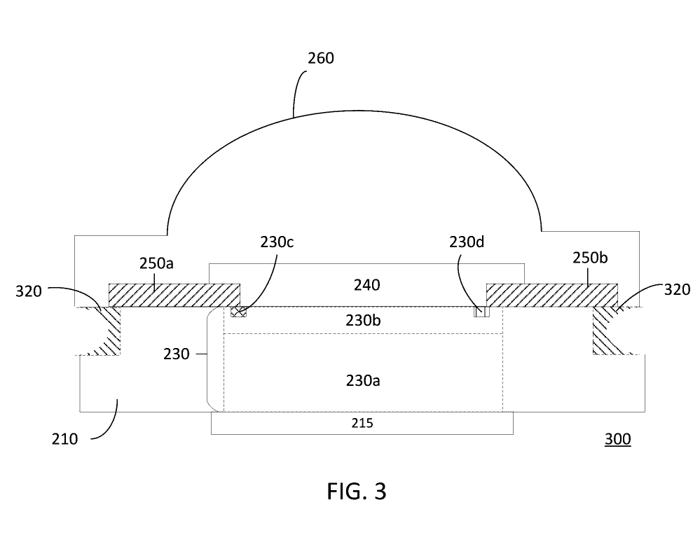

FIG. 3 provides a cross-sectional of the LED package 300 comprising the resin carrier substrate 210, wires 220, embedded LED die 230 comprising an LED substrate 230a and light emitting layer 230b, n-contact pads 230c, p-contact pads 230d, phosphor layer 240, metal interconnects 250a and 250b, and silicone dome 260, in the A-A direction as shown in FIG. 2A. In this embodiment, wires 320 are implemented as hollow wires. In contrast to non-hollow wires, diced hollow wires provide a recess defined by the interior hollow portion of the wire. These recessed portions provide an advantage of an increased surface area for electrical contact and for improved securing of the LED package to the housing.

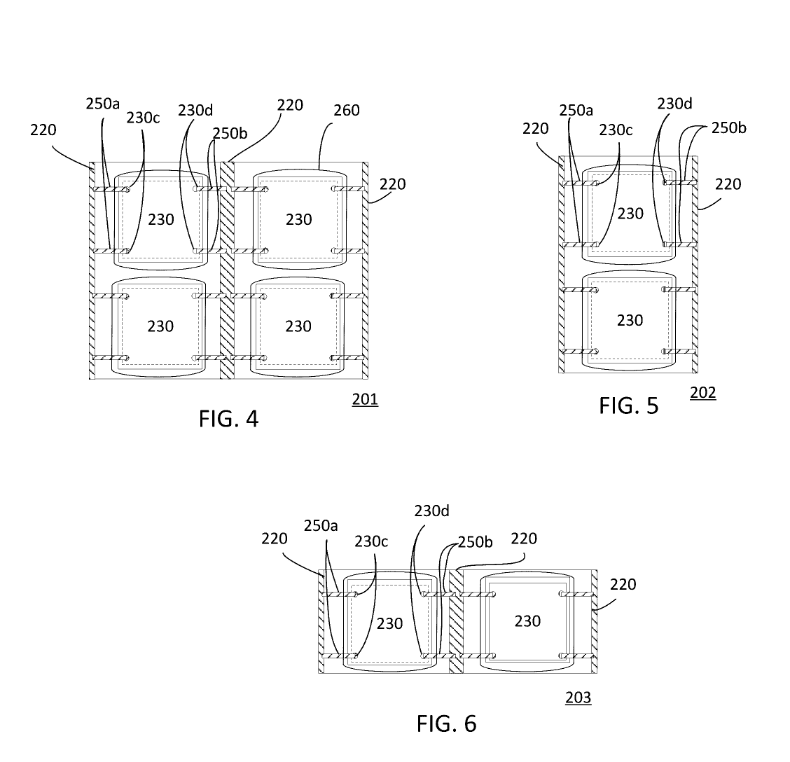

FIG. 4 provides a plan view of an LED package 201 of another embodiment of the present disclosure. The unique configuration of wires 220, n-contact pads 230c, p-contact pads 230d, metal interconnects 250a and 250b, and the LED die 230 allow for a wafer, formed using the process described later with respect to FIGS. 7A to 7K, to be diced in a variety of ways to produce multiple size LED packages. In the present disclosure, the dicing step enables the formation of multiple sized LED packages. For example, LED package 201 comprises four LED dies 230 arranged in an 2×2 array (i.e., two columns and two rows). Because of the connections provided by wires 220 and the metal interconnects 250a and 250b, the LED dies 230 are connected in parallel and in series with one another. FIG. 4 also shows silicone domes 260 over each of the LED dies 230. The planar connections between each of the silicone domes 260 are not necessarily visible in plan view, but are visible in side view. One of ordinary skill in the art would understand, despite not being visible in plan view, that there are planar connections between each of the silicone domes 260, where the planar connections are a result of the domes being formed through by compressing the silicone material over the LED package 201.

FIG. 5 provides a plan view of an LED package 202 of another embodiment of the present disclosure. In this embodiment, LED package 202 comprises two LED dies 230 arranged in a 2×1 array (i.e., two rows and a single column). In this arrangement, the two dies 230 are electrically connected to each other in parallel.

FIG. 6 provides a plan view of an LED package 203 of another embodiment of the present disclosure. In this embodiment, LED package 203 also comprises two LED dies 230, but arranged in a 1×2 array (i.e., a single row and two columns). In this arrangement, the two dies 230 are electrically connected to each other in series. FIGS. 4-6 illustrate but a few examples of LED packages that are possible because of the novel aspects described herein. One of ordinary skill in the art would recognized that other configurations are possible, and within the spirit and scope of the disclosure.

The structure of LED packages of the present disclosure, such as with LED packages 200-203, provides other advantages because of the LED die 230 being substantially embedded within resin carrier layer 210. The amount of silicone in silicone dome 260 can be reduced by up to 30% compared to the amount of silicone needed in conventional silicon dome 180 of FIG. 1. This reduction is a result of the LED die 230 being substantially embedded within the resin carrier layer 210 which allows for the upper surface of the light emitting layer 230b of the LED die 230 to be substantially planar or have a parallel relationship with the upper surface of the resin carrier layer 210. This allows for the silicone dome 260 to be formed closer to the upper surface of the LED packages 200-203.

Another advantage of the LED structures of the present disclosure is increased light extraction efficiency which results from reduced optical absorption by LED die 230. As discussed above with respect to FIG. 1, exposed sidewalls compromise the efficiency of the LED package 100 because the exposed sidewalls absorb light emitted from the light emitting layer 130. In contrast, the sidewalls of LED substrate 230a of the LED packages 200-203 are substantially embedded in the resin carrier layer 210, and thus the likelihood is reduced that light is absorbed by these sidewalls, which in turn, reduces the amount of optical absorption by the LED die 230.

LED structures of the present disclosure also have increased performance over conventional LED structures. As seen in FIG. 2B, because the bottom surface of the LED substrate 230a of the LED die 230 is exposed at the bottom surface of the LED package 200, the LED substrate 230a may be in direct contact with a backside contact pad 215 formed on the bottom surface on the LED package 200, which is in contrast to the conventional LED die 100 shown in FIG. 1. The direct contact between the LED substrate 230a and a backside contact pad 215 allows the backside contact pad 215 to dissipate the heat of the LED package 200 because of the absence of any additional intervening layers. The above examples are just some of the advantages that certain of the LED packages of the present disclosure provides over conventional LED packages.

FIGS. 7A-7K show the various steps of the fabrication method according to one embodiment of the present disclosure. The LED packages shown in these figures are exemplary and not shown to scale. One of ordinary skill in the art would understand that the LED packages are not limited to the configuration shown and may comprise additional LED dies beyond what is illustrated in the figures. For example, the LED packages may be part of a larger wafer. For the sake of simplicity, only a subset of the LED dies are illustrated. The components in FIGS. 7A-7K may be exaggerated for illustrative purposes only, and one of ordinary skill in the art would understand that other configurations for the components and LED packages are possible.

FIG. 7A provides a cross-sectional view illustrating the step of placing wires 220 and LED dies 230 comprising substrates 230a and light emitting layers 230b onto a thermal release adhesive foil 270 and a carrier substrate 280 using, for example, a pick & place tool. The carrier substrate 280 and the thermal release adhesive foil 270 may be formed as a wafer. The thermal release adhesive foil 270 may be double-sided adhesive film. In one embodiment, the side of the thermal release adhesive foil 270 that attaches to the carrier substrate 280 is designed to withstand temperatures necessary for molding the resin layer and performing the post-mold curing. In one embodiment, the side of the thermal release adhesive foil 270 opposing the carrier substrate 280, and in contact with a surface of the light emitting layers 230b, is designed to lose adhesive strength at a set temperature after the molding and post-mold curing steps. A pick & place tool may be used to mount the LED dies 230 onto the thermal release adhesive foil 270. Wires 220 may be placed by a specially designed tool to dispense desired length of straight wires and place them before or after the placement of columns of LEDs.

FIG. 7B provides a cross-sectional view illustrating the step of applying a resin carrier layer 210 over the placed wires 220, LED dies 230, and the thermally sensitive adhesive side or the thermally non-sensitive side of the thermal release adhesive foil 270. In one embodiment, the application of the resin carrier layer 210 may comprise using a compression molding process. In the step shown in FIG. 7B, the resin carrier layer 210 encapsulates the LED dies 230 and wires 220 such that the LED dies 230 and wires 220 are substantially embedded within the resin carrier layer 210. The resin carrier layer 210 does not encapsulate the top surfaces of light emitting layer 230b or wires 220, which are currently in contact with the side of the thermal release adhesive foil 270 opposing the carrier substrate 280. The LED dies 230 and wires 220 are embedded within the resin carrier layer 210 with a pre-determined pitch between the LED dies 230 and wires 220. The pitch refers to the distance or separation from the center of each die 230. For example, the pitch may be based on the width of the die and the wires 220. One of ordinary skill in the art would appreciate the appropriate pitch is generally based on the size of the LED package to be manufactured. The optimal pitch is determined by the size of the package. There is a minimum space required between LED dies 230 and wire 220 so that the resin carrier layer 210 may be properly applied. In one embodiment, the spacing should be at least 10˜20 um.

Next, the thermal release adhesive foil 270 and carrier substrate 280 is removed (not shown). Such removal is accomplished by heating the thermal release adhesive foil 270, which causes the thermally sensitive adhesive side of the thermal release adhesive foil 270 to release from the resin carrier layer 210, the LED dies 230, and wires 220 at the set temperature, which is designed to be higher than the molding and post-mold curing temperatures. FIG. 7C illustrates the step subsequent to removing the thermal release adhesive foil 270 and carrier substrate 280 from one side of the resin carrier layer 210, the LED dies 230, and the wires 220. With the carrier substrate 280 and thermal release adhesive foil 270 removed, portions of the upper surfaces of the resin carrier layer 210 and the entire upper surfaces of the light emitting layers 230b are exposed. The light emitting layers 230b are exposed at the upper surface of the resin carrier layer 210. The resin carrier layer 210, LED dies 230 comprising the LED substrates 230a and light emitting layer 330b, and the wires 220 substantially embedded within the resin carrier layer 210, form a wafer 205 which allows for subsequent steps to be performed using wafer-level processing.

FIG. 7D provides a plan view of one embodiment of wafer 205 as shown in FIG. 6C in the fabrication process after the removal of the thermal release adhesive foil 270 and carrier substrate 280. In this view, the n-contact pads 230c, p-contact pads 230d, along with the upper surfaces of resin carrier layer 210, wires 220, and LED dies 230 are visible. Although here a 2×4 array (i.e., two columns and four rows) of LED dies 230 is shown in this figure, one of ordinary skill in the art would understand that the wafer 205 may comprise an array of any number of rows and any number of columns of LED dies.

Next, the wafer level processing continues with the steps of forming the metal interconnects 250a and 250b, and the phosphor layer 240 on the LED die 230.

FIG. 7E illustrates a deposition step depositing the metal interconnects 250a and 250b over the upper surfaces of wires 220 and of light-emitting layers 230b in performing wafer-level processing on wafer 205. As previously discussed, in contrast to conventional LED package fabrication methods, wafer-level processing is possible because of the absence of fragile bond wires and the presence of a substantially planar surface on the upper surface of the wafer 205. Excess resin of the resin layer 210 on the bottom surface of the wafer 205 is ground away to expose the bottom surfaces of the LED substrates 230a. Metal interconnects 250a and 250b are then deposited on the upper surface of the wafer 205. Metal interconnects 250a are electrically connected to the n-contact pads 230c of the LED dies 230 and metal interconnects 250b are electrically connected to the p-contact pads 230d of the LED dies 230. In one embodiment, forming the metal interconnects 250a and 250b on the upper surface of the resin carrier layer 210 may also include depositing reflective metal or other reflective materials on a upper surface of the metal interconnects 250a and 250b. The purpose of the reflective metal is to minimize the optical absorption of light emitted by the light emitting layers 230b. The reflective metal therefore allows the metal interconnects 250a and 250b to (1) provide electrical connections between wires 220 and the LED dies 230 and (2) reflect photons emitted from the light emitting layers 230b (i.e., preventing the absorption of light).

Additionally, in one embodiment, a backside contact pad 215 may be formed by either deposition or electroplating process on the bottom surface of the wafer 205 and in contact with the exposed bottom surfaces of the LED substrates 230a of the LED dies 230. The backside contact pad 215 may be a thermal contact pad, which allows heat from the LED dies 230 to more easily dissipate.

FIG. 7F provides a cross-sectional view illustrating the step of forming wafer-level phosphor layers 240 and silicone domes 260 on the upper surface of the wafer 205. In contrast to conventional LED package fabrication methods, the phosphor layers 240 can be applied on the light emitting layers 230b as part of a wafer-level processing function by, for example, stencil printing or phosphor film lamination. These steps may be performed directly on the wafer 205, which was not previously possible in conventional LED fabrication steps because of the presence of fragile bond wires suspended over the LED dies and substrates. The silicone domes 260 may be formed by compression molding process after the formation of the phosphor layers 240. FIG. 7F also illustrate planar connection 265 which connect the silicone domes 260 for each LED die. As discussed above, the planar connections 265 are visible in side view.

FIG. 7G shows a plan view of one embodiment of the wafer 205 of FIG. 7F formed as a result of wafer-level processing; metal interconnects 250a and 250b, phosphor layer 240, silicone domes 260 are shown as formed directly on the wafer. Advantageously, significant time and cost savings can be achieved because these elements are formed using wafer level operations, rather than individually placing them on dies after they have been singulated from the wafer.

FIGS. 7H-7K illustrate different ways wafer 205 may be diced to produce different LED packages having different configurations and number of LED dies. Because of the unique configuration of the wires 220 and the metal interconnects 250a and 250b, wafer 205 may be diced to produce multiple size LED packages having any number of LED dies that can be adjusted based on production demands and requiring minimal changes to existing manufacturing processes. This flexibility is yet another advantage.

For example, FIG. 7H illustrates wafer 205 with dicing streets 290a, 290b, and 290c positioned along the wires 220, and dicing streets 295a, 295b, and 295c transverse to wires 220. Dicing of the wafer 205 along dicing streets 290a, 290b, and 290c extends across the entire length, L, of the wafer 205. Dicing of the wafer 205 along dicing streets 295a, 295b, and 295c extends across the entire width, W, of the wafer 205. Because of these dicing streets, multiple LED packages 200 may be formed from wafer 205. As discussed above, FIGS. 2A-2C provide alternative views of one embodiment of LED package 200. Because dicing streets 290a, 290b, and 290c result in dicing the wafer 205 along each of the wires 220, the wires 220 are exposed along the sidewalls of LED packages 200.

As another example, FIG. 7I illustrates wafer 205 with dicing streets 290a, 290b, and 290c positioned along the wires 220, and dicing street 295a transverse to the wires 220. Dicing of the wafer 205 along dicing streets 290a and 290c extends across the entire length, L, of the wafer. In contrast, dicing of the wafer 205 along dicing streets 290b only extends partly across the length, L, of the wafer. Dicing of the wafer 205 along dicing street 295a extends across the entire width, W, of the wafer 205. Because of these dicing streets, multiple LED packages 201 and 202 may be formed from wafer 205. FIG. 3 provides a view of LED package 201. FIG. 5 provides a view of one embodiment of LED package 202. Because dicing streets 290a, 290b, and 290c result in dicing the wafer 205 along each of the wires 220, the wires 220 are exposed along the sidewalls of LED packages 201 and 202.

FIG. 7J illustrates wafer 205 with dicing streets 290a, 290b, and 290c positioned along the wires 220, and dicing streets 295a and 295b transverse to the wires 220. Dicing of the wafer 205 along dicing streets 290a and 290c extends across the entire length, L, of the wafer. In contrast, dicing of the wafer 205 along dicing street 290b extends only partly across the length, L, of the wafer 205. Dicing of the wafer 205 along dicing streets 295a and 295b extends only partly across the width, W, of the wafer 205. Because of these dicing streets, multiple LED packages 202 and 204 may be formed from wafer 205. Because dicing streets 290a, 290b, and 290c result in dicing the wafer 205 along each of the wires 220, the wires 220 are exposed along the sidewalls of LED packages 202 and 204.

As another embodiment, FIG. 7K provides another embodiment for dicing the wafer 205 with dicing streets 295a, 295b, and 295c transverse to wires 220. Dicing streets 295a, 295b, and 295c extend across the entire width of the wafer 205. As a result of these dicing streets, multiple LED packages 203 may be formed from the wafer 205. FIG. 6 provides a view of one embodiment of LED package 203.

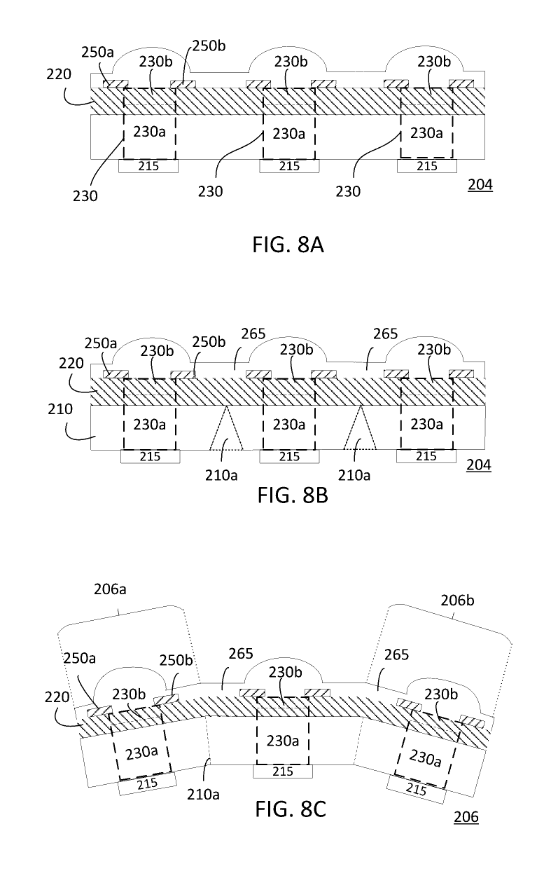

FIG. 8A provides a cross-sectional view of the LED package 204 that may be formed as a result of the dicing shown in FIG. 7J. In one embodiment, the LED package 204 having an array of at least two LED dies 230, comprising LED substrates 230a and light emitting surfaces 230b. The respective light emitting surfaces 230b have a planar relationship with each other. In one embodiment, a planar relationship refers to the top surfaces of the light emitting surfaces 230b being substantially parallel with each other.

LED packages comprising an array of at least two LED dies 230 such as, for example, LED package 204, affords another advantage not found in conventional LED packages. As will be described in FIGS. 8B and 8C, there may be lighting applications where a wider lighting pattern is needed. In these applications, it is beneficial to place neighboring LED dies within an LED package a slight angle to affect the lighting pattern of the LED package.

In FIG. 8B, portions of the resin carrier layer 210 between LED dies are removed so as to form grooves that span the length of the resin carrier layer 210. FIG. 8B shows grooves 210a as triangular in shape that run the length of the resin carrier layer 210. While shown as having a triangular shape, the grooves 210a may be formed in the resin carrier layer 210 into any shape that would permit the light emitting surfaces 230b to form a non-planar, angled relationship. The depth of the grooves 210a may reach the wires 220. The number of grooves 210a and the depth of grooves 210a depends on the amount of flexing or the type of non-planar shape. FIG. 8B also illustrate planar connections 265 which connect the silicone domes 260 for each LED die 230.

By removing certain portions of the resin carrier layer 210 and using a flexible wire 220, the arrangement of LED dies 230 and wire 220 may be angled such that the light emitting surfaces 230b have a non-planar and an angled (i.e., non-parallel) relationship with one another. FIG. 8C provides a view of LED package 204 with certain segments 206a and 206b of the LED package 204 pushed along the grooves 210a into a non-planar arrangement to form a differently shaped LED package 206. In contrast to the light emitting surfaces 230b shown in FIG. 8A, the light emitting surfaces 230b form a non-planar, angled relationship with each other. The angled relationship refers to the angle between neighboring light emitting surfaces 230b (i.e., non-parallel) and may be as large as 45 degrees. The planar connections 265 are flexible and conform to the angular relationship between the light emitting surfaces 230b. To allow the LED package to bend, grooves 210a may extend all the way to the wire 220. Other physical properties of the grooves 210a, such as the width of the opening end of the grooves 210a and the height of the wire 220 also may determine the maximum angle at which LED package 204 may be angled.

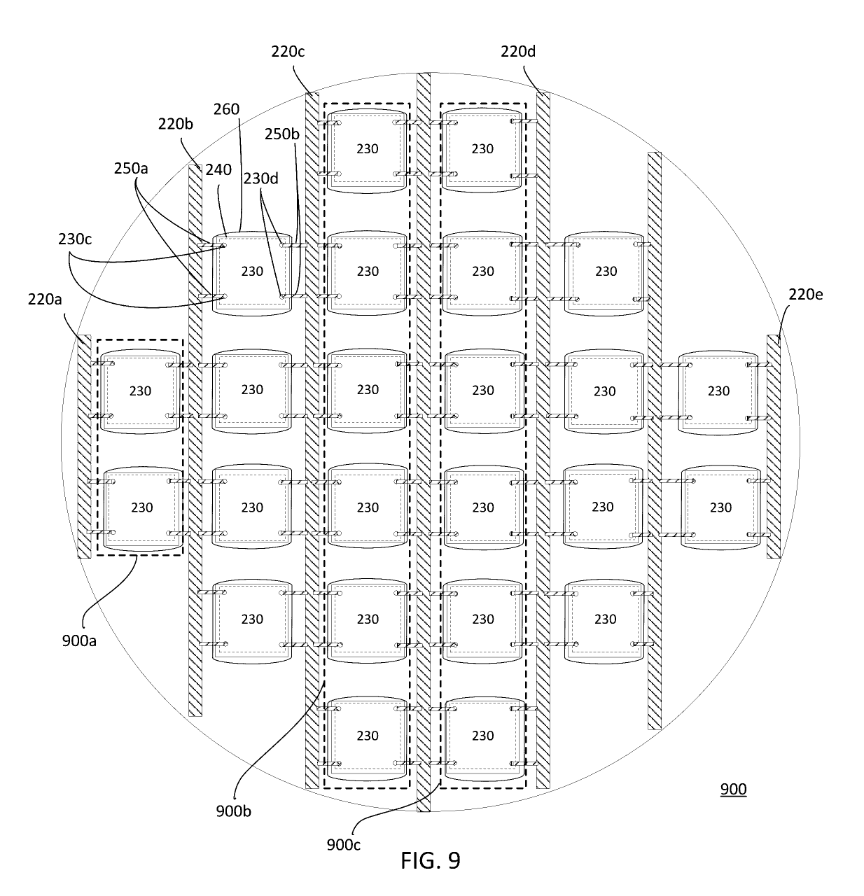

FIG. 9 provides a plan view of another embodiment of wafer 900 having a 6×6 array (i.e., six columns and six rows). In this embodiment, there is one wire between each column of LED dies 230. For example, wires 220a, 220b, 220c, 220d, and 220e are parallel to each other when formed on the wafer 900. Metal interconnects 250a are in electrical contact with n-contact pads 230c of each LED die 230 and metal interconnects 250b are in electrical contact with p-contact pads 230d of each LED die 230. The metal interconnects 250a and 250b electrically connect the LED dies 230 to each of the wires on wafer 900. Phosphor layer 240 and silicone dome 260 cover each LED die 230. One of ordinary skill in the art would understand that the wafers and LED packages described in the present disclosure are not necessarily limited to the shapes and sizes illustrated in this disclosure. Because of the unique arrangement of the wires, LED dies, and metal interconnects, the configuration of the wafers and LED package of the present disclosure are highly flexible, and can accommodate multiple shapes and sizes. The planar connections between each of the silicone domes 260 are not necessarily visible in plan view.

The parallel electrical connection enabled by wires 220a-e allows for batch testing of the LED wafer. Multiple LED dies 230 can be tested simultaneously while on the LED wafer 900 by applying an electrical current to wires 220a-e on portions of or the entire wafer 900. To test the entire wafer, a sufficiently high voltage is applied across two wires 220a and 220e, which should result in all of the LED dies 230 lighting up uniformly. LED dies 230 that do not light up indicates a malfunction with those LED dies 230. Moreover, different portions of the wafer column may also be tested. For example, a sufficiently high voltage may be applied across wires 220a and 220b to test a first column 900a of the wafer. As another example, a sufficiently high voltage may be applied across wires 220c and 220d to test two columns 900b and 900c. These tests indicate an existence of one or more of defective LEDs and/or metal interconnect. If a defect(s) is detected with respect to one or more LED dies 230 on the wafer 900, it is possible to mark or identify the errors while the LED dies 230 are still on the wafer 900. If there is a detected defect, such as a defective LED die or defective metal interconnect, the malfunctioning components may be discarded or ignored during the dicing step. This form of batch testing of the LED dies 230 represents an improvement over prior art testing because malfunctioning components are easier to detect and more easily discarded using existing manufacturing processes.

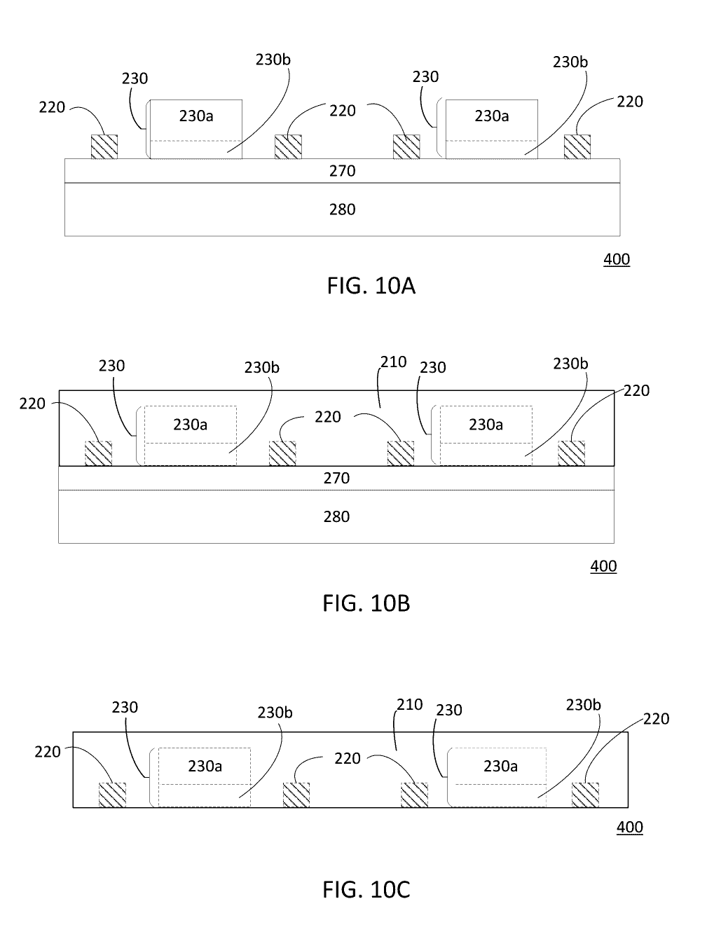

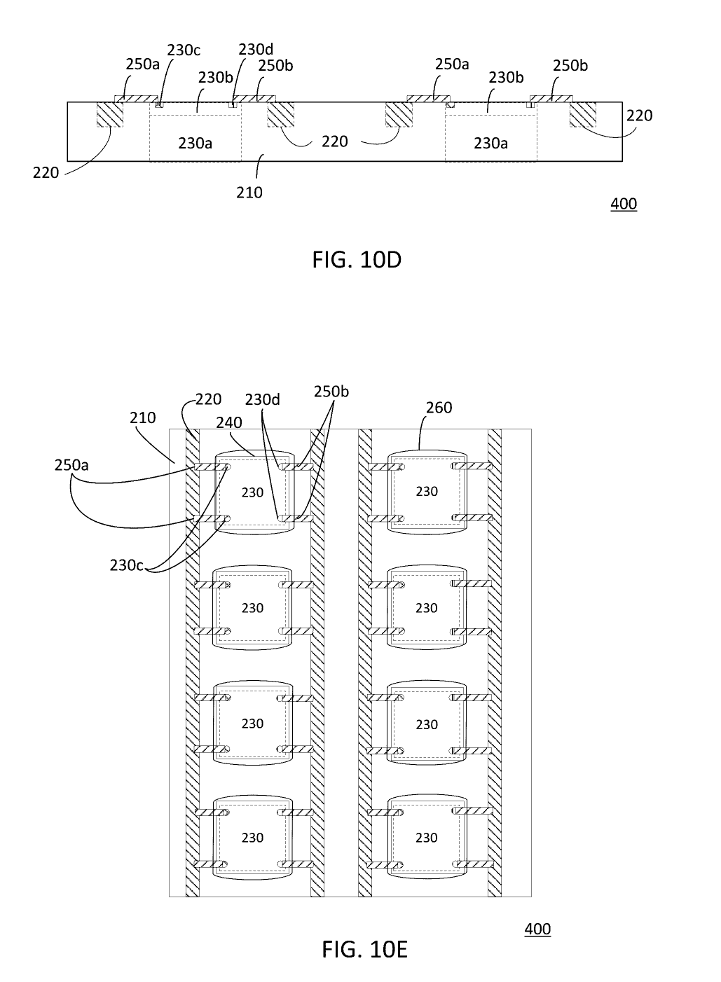

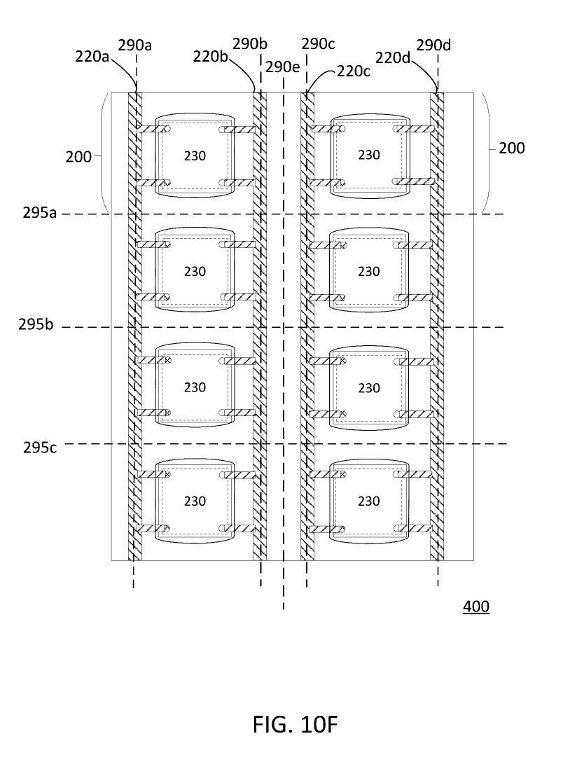

FIGS. 10A-10F show steps for forming a wafer according to another embodiment of the present disclosure. The wafers shown in FIGS. 10A-10F are merely exemplary and are not shown to scale. The components in FIGS. 10A-10F may be exaggerated for illustrative purposes only and other configurations for the components and wafers are possible.

FIG. 10A illustrates a cross-sectional view of wafer 400 after wires 220 and LED dies 230 (each comprising a LED substrate 230a and a light emitting layer 230b) have been placed on a thermal release adhesive foil 270 and a carrier substrate 280. As shown, there are two wires 220 positioned between the LED dies 230.

FIG. 10B illustrates a cross-sectional view of wafer 400 after the formation of the resin carrier layer 210, which may for example, comprise an epoxy molding compound, that encapsulates the LED dies 230 (each comprising a LED substrate 230a and light emitting layer 230b).

In FIG. 10C, the carrier substrate 280 and thermal release adhesive foil 270 have been removed exposing the upper surfaces of wires 220 and the light emitting layers 230b of the LED dies 230. The sides of the LED substrates 230a and light emitting layers 230b are encapsulated by the resin carrier layer 210. The wafer 400 is now ready for wafer-level processing steps to complete the fabrication of the LED packages.

FIG. 10D illustrates a cross-sectional view of wafer 400 after the grinding of the bottom surface of the resin carrier layer 210, which results in the exposure of the bottom surface of the LED substrates 230a. Additionally, metal interconnects 250a and 250b are formed using wafer-level processing. Metal interconnects 250a connect the n-contact pads 230c of the LED dies 230 to wires 220 and metal interconnects 250b connects the p-contact pads 230d of the LED dies 230 to wires 220.

FIG. 10E shows a plan view of the top side of one embodiment of wafer 400 after wafer-level formation of phosphor layers 240 and silicone domes 260. The phosphor layers 240 are deposited above each LED die 230 and metal interconnects 250a and 250b. The silicone domes 260 are then formed to encapsulate each LED die 230. As a result of these steps, wafer 400 may be formed and is ready for dicing to produce multiple size LED packages. One of ordinary skill in the art would understand that wafer 400 may comprise an array of any number of rows and any number of columns. In the embodiment shown in FIG. 10E, wafer 400 has an array of four rows and two columns of LED dies. Wafer 400 also has two parallel wires 220 between each column of LED dies 230, which is one of the primary features of this embodiment. Wafer 400 may be diced to produce the same types of LED packages discussed above with respect to FIGS. 7H-7K.

FIG. 10F shows dicing streets 290a, 290b, 290c, and 290d that result in dicing along wires 220a, 220b, 220c, and 220d, respectively, and dicing streets 295a, 295b, and 295c that result in dicing across wires 220a-d. As a result of this dicing, multiple LED packages 200 may be formed. Because dicing streets 290a, 290b, 290c, and 290d result in dicing the wafer 205 along each of the wires 220a-d, the wires 220a-d are exposed along the sidewalls of each of the multiple LED packages 200. The dicing configuration of wafer 400 is not limited to the dicing streets shown in FIG. 10F. Other dicing configurations are possible and can be adjusted to accommodate changing production demands for different packages. In one embodiment, the dicing can be done along 290e instead of 290b and 290c, and along 290a and 290d, which would result in only exposing the sidewalls of wires 220a and 220d.

Different types of housing for the LED assemblies are possible that take advantage of the novel LED packages described in this disclosure. The LED assemblies comprise a housing and an LED package, or packaged LED, contained within the housing. The shape of the LED assemblies can be modified depending on the type of application. The LED assembly comprises contacts located on the sidewalls of the housing, which form an electrical connection with the wires of the LED package. The contacts are in direct physical contact with the wires of the LED package. Having the electrical connections of the LED packages located at the sidewalls of the LED packages allow for a low-profile installation where the LED package is contained within a recess of the housing that is not possible with conventional LED packages. An LED assembly comprising a housing and an LED package of the present disclosure may be attached to a circuit board that drives the LED package.

FIG. 11A provides a plan view of an assembly 1100 comprising a housing 1110 with contacts 1120 that electrically connect, for example, through a direct physical connection, to the wires 220 of the LED package 200. LED package 200 and its elements are discussed with respect to, for example, FIGS. 2A-2B. Wires 220 act as electrodes for the LED package 200. In one embodiment, the housing 1100 comprises four contacts 1120 positioned on sidewalls 1130 and 1140 of the housing 1110. Two contacts 1120 are positioned on a first sidewall 1130 of the housing 1110, and two contacts 1120 are positioned on a second sidewall 1140, opposing the first sidewall 1130, of the housing 1110.

The number of contacts may vary and generally depends on the particular application. One factor that might be relevant in determining the number of contacts is whether the provided contacts have sufficient current carrying capacity. For example, as the number of LEDs in an LED package increases, the wires may carry more current, which, in turn, increases the amount of current that needs to pass through these contacts. Therefore, under this example, the contact area of the contacts should also increase to accommodate the increased current requirement. In one embodiment, this may be accomplished by, for example, increasing the number of contact points (i.e., the number of contacts) or increasing the size of the contact.

Contacts 1120 also secure the LED package 200 in place within the housing 1110. In one embodiment, contacts 1120 are spring-loaded or flexible and hold the LED package 200 in place by exerting force on the LED package 200. Here, contacts 1120 retract into or are pressed towards the housing 1110 when a force is exerted upon them, which allows the LED package 200 to be inserted into the housing 1110. This retraction provides sufficient room for the LED package 200 to be inserted into the housing 1110. When the LED package 200 is in place between the contacts 1120, the contacts 1120 exert a force on opposing sides of the LED package 200, thereby securing the LED package 200 within the housing 1110. One of the wires 220 in electrical connection with a contact 1120 acts as a cathode, and the other wire 220 is in electrical contact with another contact 1120 acts as an anode.

Using contacts 1120 to secure the LED package 200 provides other advantages as well. For example, any differences in thermal expansion between the LED package 200 and the housing 1110 may be accommodated by the contacts 1120. This is in contrast to conventional housings, which require an LED package to be soldered or glued to the housing. The problem with said conventional approach is that solder or glue are inflexible materials which may lead to cracks or other stress-related reliability problems arising from the difference in thermal expansion between an LED package and its housing. Additionally, replacing the LED package 200 is also simplified since it is no longer necessary to solder or use epoxy or glue to secure the LED package 200. Instead, contacts 1120 of the present disclosure, such as spring-loaded electrical connections, allow the LED package 200 to simply be removed, and another package to be quickly inserted between the contacts 1120 in the housing 1110.

FIG. 11B shows a cross-sectional view of the assembly 1100 illustrated in FIG. 11A as viewed from the A-A direction. As seen in this view, the housing 1110 of assembly 1100 is recessed, which allows the LED package 200 to be positioned therein to minimize the height of the LED package 200. LED package 200 and its elements are discussed with respect to, for example, FIGS. 2A-2B. This allows the housing 1110 and LED package 200 to be suitable for low-profile applications such as within mobile devices. Backside contact pad 215, discussed in more detail with respect to FIG. 2B, is also in contact with the bottom portion 1150 of the housing, which allows for heat dissipation of the LED package 200 through the housing 1110.

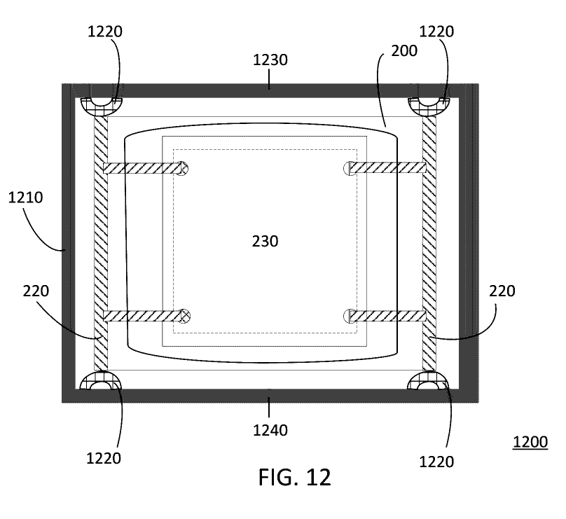

Because wires 220 span the length of the package 200, there can be a variety of different configurations for the housing beyond what is described in FIGS. 11A-11B. FIGS. 12-20B provide examples of the different possible configurations for the LED assembly of the present disclosure. Each of the figures illustrates a different embodiment of the LED assembly.

FIG. 12 provides a plan view of assembly 1200 with the contacts 1220 located on different opposing sidewalls 1230 and 1240 of the housing 1210, but still in electrical connection with the wires 220. The contacts 1220 secure the LED package 200 in place within the housing 1210 by exerting force on opposing sidewalls of the LED package 200. LED package 200 and its elements are discussed with respect to, for example, FIGS. 2A-2B. The placement of the contacts on different sidewalls of the housing may depend on the particular application or implementation of the LED assembly. The location of the various contacts can be changed to accommodate the needs of the application. In this embodiment, contacts 1220 are spring-loaded.

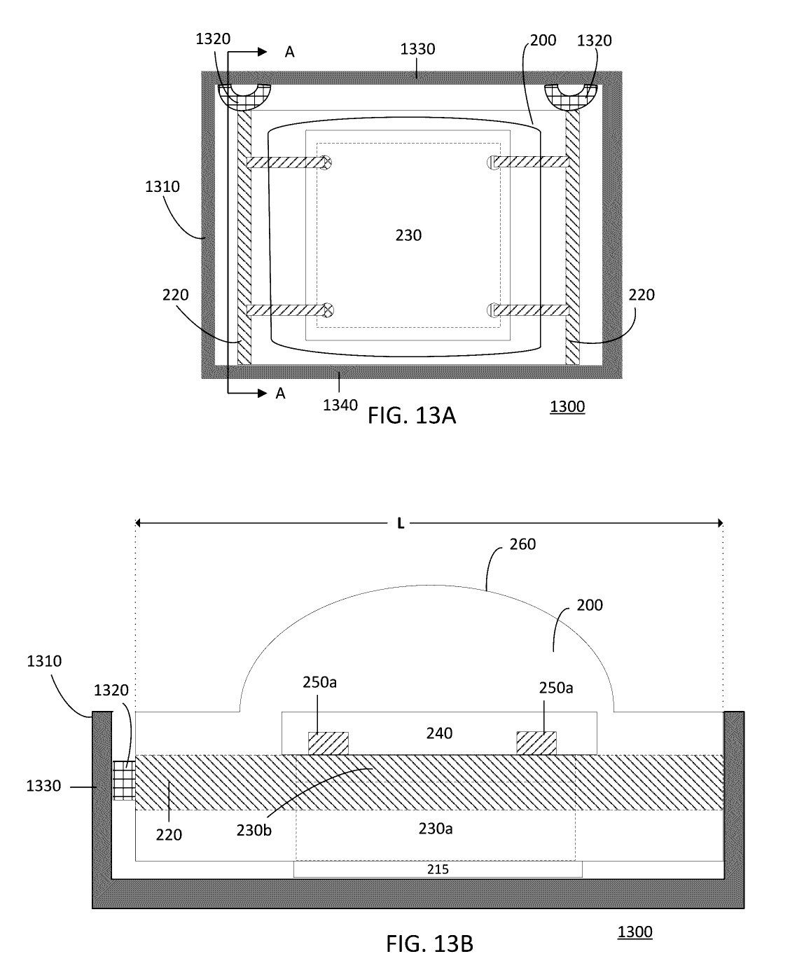

FIG. 13A provides a plan view of another embodiment of an assembly 1300 comprising a housing 1310 with contacts 1320 located only on sidewall 1330 and an LED package 200 with wires 220 which act as electrodes for the LED package 200. LED package 200 and its elements are discussed with respect to, for example, FIGS. 2A-2B. Contacts 1320 are located on the sidewall 1330 of the housing 1310, but in contact with different wires 220. In this embodiment, contacts 1320 secure the LED package 200 against an opposing sidewall 1340 by exerting force on the LED package 200.

FIG. 13B shows a cross-sectional view of the assembly 1300 of FIG. 13A taken in the A-A direction. One contact 1320 is visible in this view. Wire 220 spans the length, L, of the LED package 200. In this embodiment, contacts 1320 are spring-loaded. As with other embodiments involving spring-loaded connections, the LED package 200 may be inserted into the housing 1310 by pushing against the contacts 1320 which causes them to compress. When the LED package 200 is in place, contacts 1320 exert force to on the LED package 200 against the opposing sidewall 1340 to secure the LED package 200 within the housing 1310.

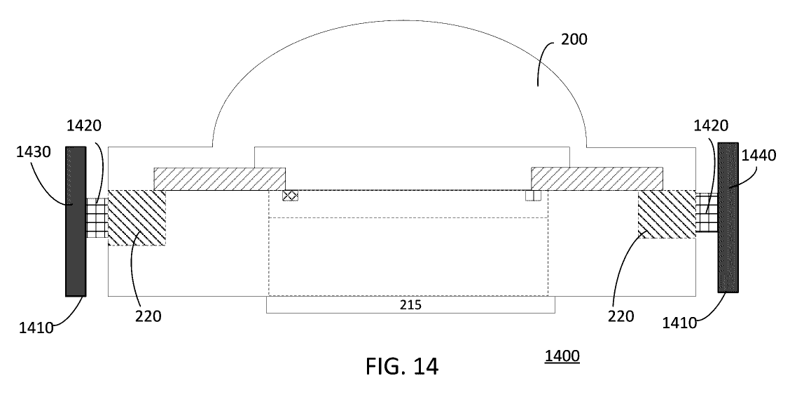

FIG. 14 shows another embodiment of an assembly 1400 with housing 1410 and LED package 200. LED package 200 and its elements are discussed with respect to, for example, FIGS. 2A-2B. The housing 1410 comprises two posts 1430 and 1440, each with contacts 1420 that are in electrical connection with wires 220, which act as electrodes for the LED package 200. In one embodiment, the posts 1430 and 1440 of the housing 1410 are attached to the surface of a circuit board (not shown) that drives the LED package 200 within the housing 1410. The structure of the housing 1410 is rigid as a result of attaching the posts 1430 and 1440 to the circuit board (not shown). The housing 1410 does not have a bottom portion in contact with the backside contact 215. Assembly 1400 may be advantageous in various applications including, for example, when heat dissipation through the backside contact pad 215 and a bottom portion of housing 1410 is not required, and when minimizing the height of the LED package 200 is a priority. It can also be advantageous: (1) when the circuit board that incorporates the LED housing is placed on another fixture, which could provide better heat dissipation than through the circuit board itself, or (2) when the LED housing is incorporated onto a fixture separated from the circuit board.

In one embodiment, posts 1430 and 1440 of the housing 1410 are plastic and comprise contacts 1420, which are spring-loaded for providing an electrical connection to the wires 220, and for securing the LED package 200. In another embodiment, posts 1430 and 1440 are constructed entirely of metal without contacts 1440. When formed of metal, posts 1430 and 1440 form an electrical connection with the wires 220 through direct physical contact. With either material, posts 1430 and 1440 can be fixed directly to a circuit board (not shown).

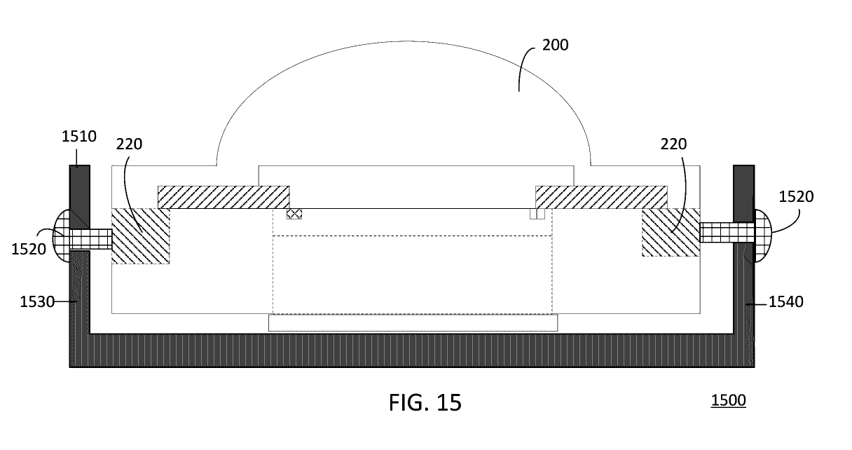

FIG. 15 shows another embodiment of an assembly 1500 comprising housing 1510 where the contacts 1520 are implemented as bolts that electrically connect to the wires 220 of the LED package 200. LED package 200 and its elements are discussed with respect to, for example, FIGS. 2A-2B. Contacts 1520 are located on a first sidewall 1530 and a second sidewall 1540 of the housing 1510. When implemented as bolts, contacts 1520 serve the same purpose as spring-loaded contacts, but have an added functionality where they may be tightened to secure the LED package 200 in place, or loosened to allow for removal of the LED package 200.

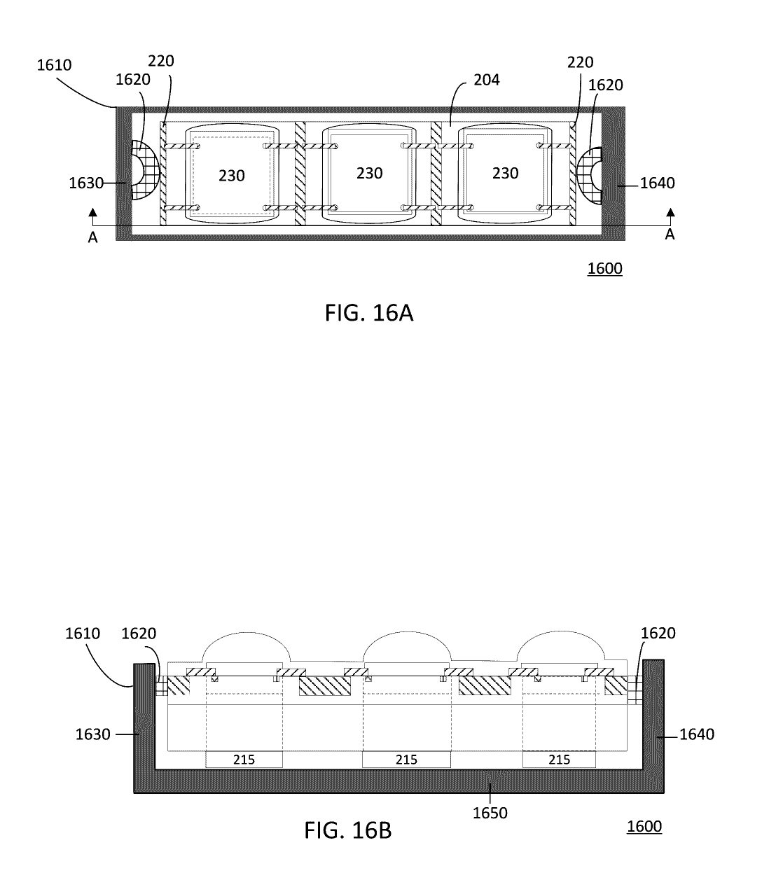

FIG. 16A shows a plan view of another embodiment of an assembly 1600 comprising a housing 1610 that accommodates an LED package 204 having three LED dies 230. LED package 204 and its respective elements were discussed with respect to FIG. 8A. Contacts 1620 are positioned on opposing sidewalls 1630 and 1640 of the housing 1610, and are in electrical contact with wires 220 that act as electrodes for the LED package 204. In this embodiment, the LED dies 230 are connected in series. One contact 1620, positioned on a first sidewall 1630 of the housing 1610, is in contact with a wire 220 acting as a cathode for the LED package 204. Another contact 1620, positioned on a second sidewall 1640 is in contact with a wire 220 acting as an anode for the LED package 204. As discussed above, the number and size of contacts 1620 may vary depending on the application or needs of the LED package. Contacts 1620 comprise a spring-loaded connection.

FIG. 16B shows a cross-sectional view of the assembly 1600 with housing 1610 viewed in the A-A direction. Backside contact pads 215, discussed in more detail with respect to FIG. 2B, are in contact with the bottom portion 1650 of the housing, which allows for heat dissipation of the LED package 200 through the housing 1610.

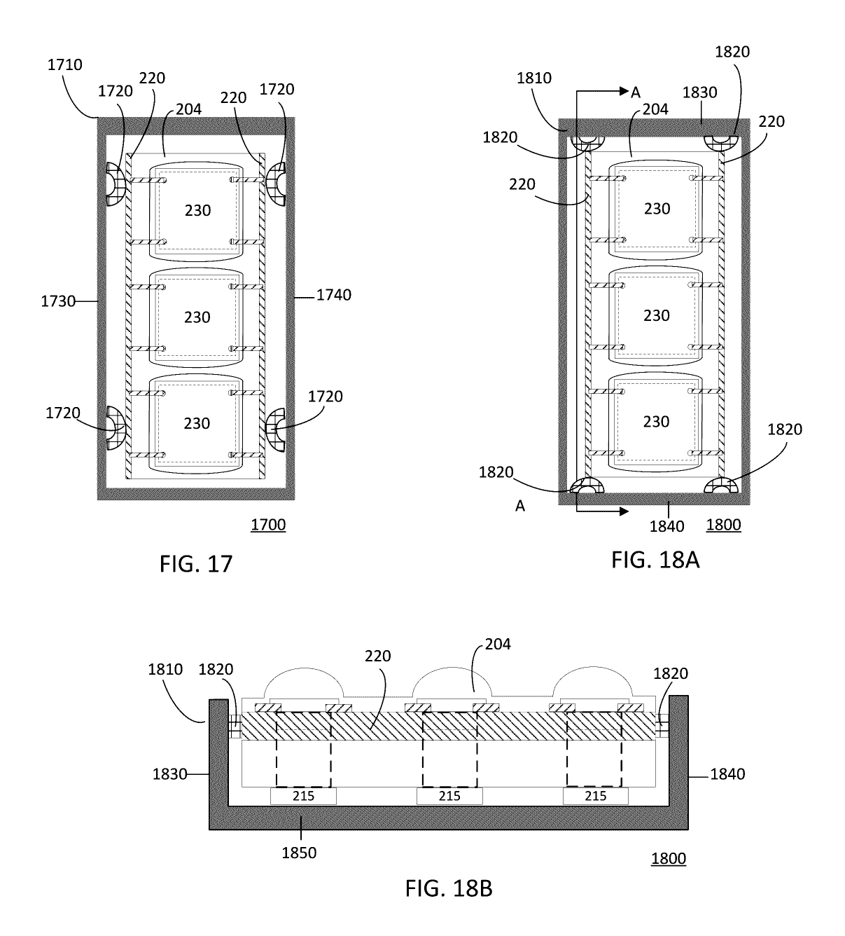

FIG. 17 shows a plan view of another embodiment of an assembly 1700 comprising housing 1710 that accommodates an LED package 204 having three LED dies 230 connected in parallel. LED package 204 and its respective elements were discussed with respect to FIG. 8A. Two contacts 1720 are positioned on a first sidewall 1730 and are electrically connected, through direct physical contact, to a wire 220 acting as a cathode for the LED package 204. Two contacts 1720 are positioned on a second sidewall 1740 and are electrically connected, through direct physical contact, to a wire 220 acting as an anode for the LED package 204.

FIG. 18A shows a plan view of another embodiment of an assembly 1800, with contacts 1820 positioned on different opposing sidewalls 1830 and 1840 of the housing 1810, but still in electrical connection with wires 220. Two contacts 1820 are positioned on a sidewall 1830, and two contacts 1820 are positioned on an opposing sidewall 1840. The contacts 1820 positioned on the sidewall 1830 are connected to different wires 220 of the LED package 204 having three LED dies 230 connected in parallel, and contacts 1820 positioned on the opposing sidewall 1840 are connected to different wires 220 of the LED package 204. LED package 204 and its respective elements were discussed with respect to FIG. 8A.

FIG. 18B provides a cross-sectional view of the assembly 1800 of FIG. 18A taken along the A-A direction. Wire 220 spans the length of the LED package 204. Backside contact pads 215, discussed in more detail with respect to FIG. 2B, are in contact with the bottom portion 1850 of the housing, which allows for heat dissipation of the LED package 200 through the housing 1810.

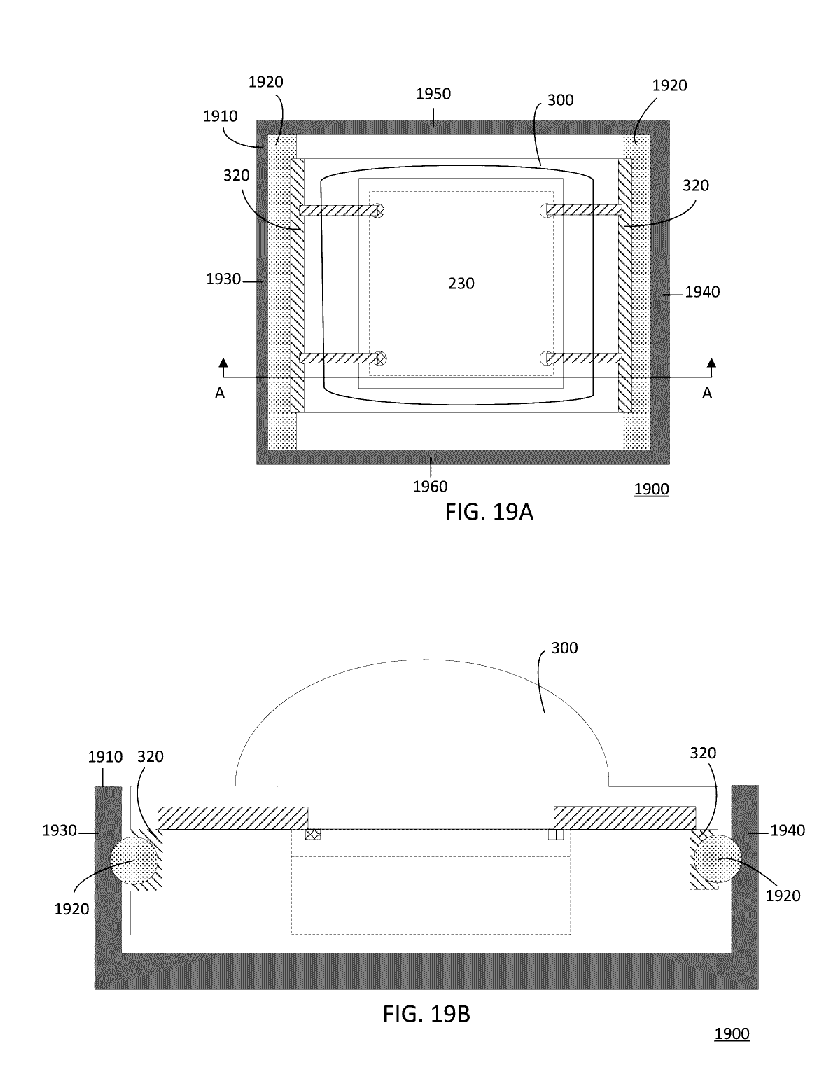

FIG. 19A shows a plan view of another embodiment of an assembly 1900 comprising a housing 1910 comprising contact wires 1920 that accommodate an LED package 300 having wires 220, which act as electrodes for the LED package 200. LED package 300 having hollow wires 320 and its respective elements were discussed in detail with respect to FIG. 3. A first contact wire 1920 is positioned along the first sidewall 1930, and a second contact wire 1920 is positioned along the second sidewall 1940, opposing the first sidewall 1930. Interior portions of the sidewalls 1930 and 1940 are recessed to accommodate each of the contact wires 1920. The contact wires 1920 provide an electrical connection with hollow wires 320 of the LED package 300, and secure the LED package 200 in place within the housing 1910. First ends of the contact wires 1920 may be affixed to a third sidewall 1950 of the housing 1910, and opposing ends of the contact wires 1920 may be affixed to a fourth sidewall 1960 of the housing 1910.

FIG. 19B provides a cross-sectional view of the assembly 1900 along the A-A direction of FIG. 19A. Therefore, diced hollow wires 320 comprise a recessed portion. Housing 1910 comprises contact wires 1920 positioned on opposing sidewalls of the housing 1910, and the contact wires 1920 are positioned within the recessed portion of the hollow wires 320. The size of the recessed portion of the hollow wires 320 are configured so that the recessed portion can accommodate the contact wires 1920. The contact wires 1920 form an electrical connection with hollow wires 320 when in physical contact, and secure the LED device in place within the housing 1910.

While discussion of the contact wires 1920 has been in relation to hollow wires 320, one of ordinary skill in the art would understand that the use of contact wires 1920 is not necessarily limited to hollow wires, and can be utilized with other types of wires as long as the contact wires 1920 can form an electrical connection with the LED package. For example, contact wires 1920 may also be used with non-hollow wires, as described with respect to the LED package shown in FIG. 11A.

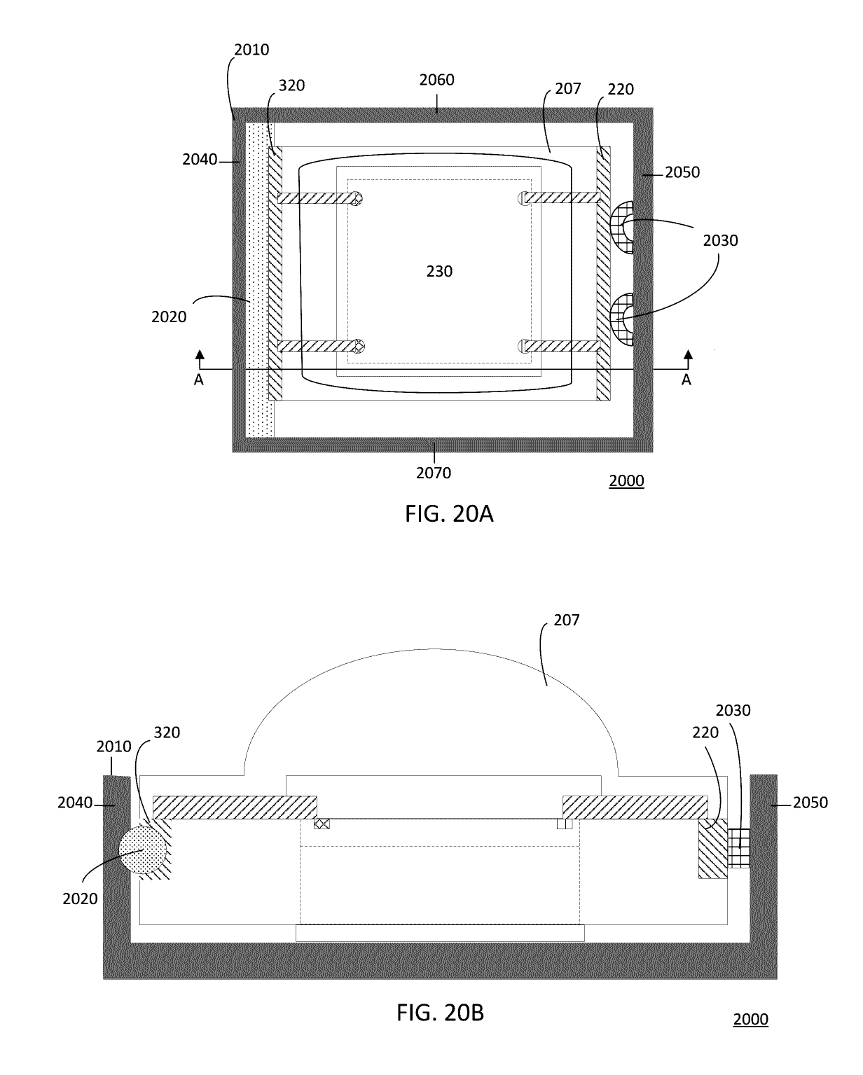

FIG. 20A shows a plan view of another embodiment of an assembly 2000 comprising a housing 2010 and LED package 207. LED package 207 comprises hollow wire 320 and solid wire 220. The housing 2010 comprises a contact wire 2020 and contacts 2030. A contact wire 2020 is positioned along a recess within an interior portion of a first sidewall 2040 of the housing 2010 and contacts 2030 are positioned along a second sidewall 2050 of the housing 2010. One end of the contact wire 2020 may be affixed to a third sidewall 2060 of the housing 2010, and an opposing end of the contact wire 2020 may be affixed to a fourth sidewall 2070, opposing the third sidewall 2060, of the housing 2010. The contact wire 2020, through direct physical contact, is in electrical connection with the hollow wire 320 of the LED package 200, and contacts 2030, through direct physical contact, is in electrical connection with solid wire 220 of the LED package 207.

FIG. 20B provides a cross-sectional view of the assembly 2000 of FIG. 20A viewed from the A-A direction. Contact wire 2020, through direct physical contact, is in electrical connection with the hollow wire 320. Therefore, diced hollow wire 320 comprises a recessed portion, and the contact wire 2020 is positioned within the recessed portion of the wire 220. As depicted in the figure, the solid wire 220 in direct physical contact with contacts 2030 but may also be hollow. Contacts 2030, through direct physical contact, are in electrical contact with solid wire 220. In one embodiment, contacts 2030 are spring-loaded.

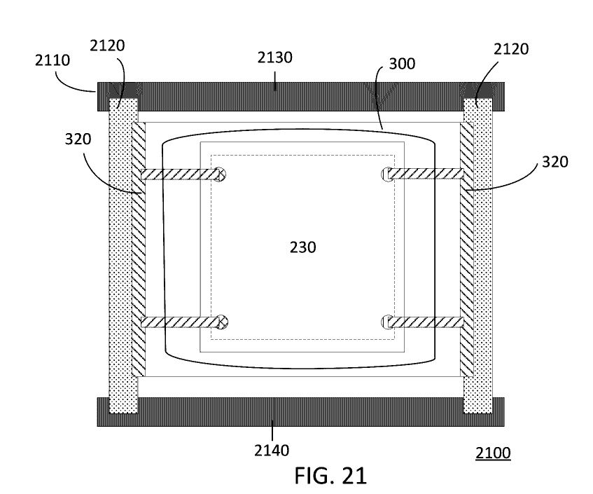

FIG. 21 provides a plan view of another embodiment of assembly 2100 comprising a housing 2110 and LED package 300 comprising LED die 230 and hollow wires 320. LED package 300 and its respective elements were discussed with respect to FIG. 3. Housing 2110 comprises a first sidewall 2130 and a second sidewall 2140, opposite the first sidewall 2130, that are connected to each other by contact wires 2120. First ends of the contact wires 2120 are affixed to the first sidewall 2130 of the housing 2110, and second ends, opposing the first ends, of the contact wire 2120 are affixed to the second sidewall 2140 of the housing 2110. The rigidity of the structure is provided by securing the sidewalls 2130 and 2140 to a circuit board (not shown), and through the wire contacts 2120 that connect the sidewalls. The contact wires 2120, through direct physical contact, are in electrical connection with hollow wires 320 of the LED package 300. Sidewalls 2130 and 2140 are configured to keep the contact wires 2120 in direct physical contact with the hollow wires 320 of the LED package.

Other objects, advantages and embodiments of the various aspects of the present disclosure will be apparent to those who are skilled in the field of the invention and are within the scope of the description and the accompanying Figures. For example, but without limitation, structural or functional elements might be rearranged consistent with the present disclosure. Similarly, principles according to the present invention could be applied to other examples or configurations for the LED packages, which, even if not specifically described here in detail, would nevertheless be within the scope of the present invention.

What is claimed is:

1. A light-emitting diode (LED) assembly comprising:
a packaged LED including:
a first electrode that is substantially exposed along a first sidewall of a resin carrier layer of the packaged LED, and
a second electrode that is substantially exposed along a second sidewall of the resin carrier layer; and
a housing accommodating the packaged LED comprising:
a first contact positioned on a first inward facing sidewall of the housing and electrically connected to the first electrode of the packaged LED, and
a second contact positioned on a second inward facing sidewall of the housing and electrically connected to the second electrode of the packaged LED.

2. The LED assembly of claim 1, wherein the first inward facing sidewall of the housing is opposite to the second inward facing sidewall of the housing.

3. The LED assembly of claim 1, wherein the first inward facing sidewall of the housing is the same as the second inward facing sidewall of the housing.

4. The LED assembly of claim 1, wherein the housing further comprises third and fourth contacts.

5. The LED assembly of claim 4, wherein:
the third contact is positioned on the first inward facing sidewall of the housing, and electrically connected to the first electrode of the packaged LED.

6. The LED assembly of claim 4, wherein:
the third contact is positioned on the second inward facing sidewall of the housing, and electrically connected to the first electrode of the packaged LED.

7. The LED assembly of claim 4, wherein:
the fourth contact is positioned on the first inward facing sidewall of the housing, and electrically connected to the second electrode of the packaged LED.

8. The LED assembly of claim 4, wherein:
the fourth contact is positioned on the second sidewall of the housing, and electrically connected to the second electrode of the packaged LED.

9. The LED assembly of claim 1, wherein the first contact is configured to be in direct physical contact with the first electrode of the packaged LED and the second contact is configured to be in direct physical contact with the second electrode of the packaged LED.

10. The LED assembly of claim 9, wherein the first and second contacts secure the packaged LED within the body.

11. The LED assembly of claim 1, wherein the first and second contacts comprise spring-loaded electrical connection with the electrode of the LED package.

12. The LED assembly of claim 1, wherein the first and second contacts are adjustable bolts.

13. The LED assembly of claim 1, wherein the first contact is a contact wire and the second contact is a second contact wire.

14. The LED assembly of claim 13, wherein a first end of the first contact wire is attached to the first sidewall of the housing and a second end of the first contact wire is attached to the second sidewall of the housing.

15. The LED assembly of claim 1, wherein the housing comprises a recess and the recess accommodates the packaged LED.

16. The LED assembly of claim 1, further comprising:
a bottom portion configured to be in contact with a bottom side of the packaged LED.

17. The LED assembly of claim 16, wherein the bottom portion of the LED housing is a heat dissipater.

18. The LED assembly of claim 1, wherein the first sidewall of the LED package and the second sidewall of the LED package are on opposite sides of the LED package.
